(19) United States
(12) Patent Application Publication
(10) Pub. No.: US 2009/0290322 A1
(43) Pub. Date: Nov. 26, 2009

(54) ENCLOSURE OPERABLE BETWEEN UNLOCKED AND LOCKED STATES AND INCLUDING A SWITCH DEVICE

(75) Inventor: Wen-Jung CHANG, Changhua Hsien (TW)

Correspondence Address: MCNEES WALLACE & NURICK LLC, 100 PINE STREET, P.O. BOX 1166, HARRISBURG, PA, 17108-1166, US

(73) Assignee: UNIVERSAL SCIENTIFIC INDUSTRIAL CO., LTD., Nan-Tou Hsien (TW)

(21) Appl. No.: 12/123,878

(22) Filed: May 20, 2008

(51) Int. Cl. H05K 7/00

(52) U.S. Cl. 361/837

(57) ABSTRACT

An enclosure includes a cover body for covering a housing, and a switch device that includes a lock plate connected pivotally to the cover body and connected to an operating plate mounted movably on the cover body via a connecting bolt extending through the operating plate, the cover body and an inclined guide slot in the lockplate. To switch the enclosure from a locked state, where the lock plate engages a retaining recess in the housing, to an unlocked state, where the lock plate extends into a notch in the housing, the operating plate is moved in a direction so that the lock plate is rotated to disengage the retaining recess, and the cover body is then moved in the direction until the lock plate extends into the notch. When the lock plate extends into the notch, removal of the cover body is allowed.

### BACKGROUND OF THE INVENTION

1. Field of the Invention

The invention relates to an enclosure, more particularly to an enclosure including a switch device.

2. Description of the Related Art

Referring to FIGS. 1 and 2, a conventional enclosure is shown to include a lower housing 1, an upper cover body 2 mounted movably on the lower housing 1, and a resilient lock plate 3 mounted on the upper cover body 2. The lower housing 1 has opposite lateral guide rails 101, one of which is formed with a notch 102, an engaging slot 104 disposed adjacent to the notch 102, and an inclined guide surface 103 disposed between the notch 102 and the engaging slot 104. The upper cover body 2 has opposite downward extending lateral flanges 201 abutting respectively against the lateral guide rails 101 of the lower housing 1, and is formed with a through hole 202. The lock plate 3 is disposed on a bottom surface of the upper cover body 2, and has a connecting end portion fixed to the bottom surface of the upper cover body 2 using two connecting rods 203 that extend downwardly from the bottom surface of the upper cover body 2 and through the connecting end portion, and a lock end portion opposite to the connecting end portion and having an engaging rod 302, and an intermediate operating portion interconnecting the connecting end portion and the lock end portion and formed with a protruding button 301 extending upwardly through the through hole 202 in the upper cover body 2.

The conventional enclosure is operable between an unlocked state, where the upper cover body 2 partly covers the lower housing 1 while the engaging rod 302 extends into the notch 102 in the lateral guide rail 101, and a locked state, where the upper cover body 2 fully covers the lower housing 1 while the engaging rod 302 engages the engaging slot 104 in the lateral guide rail 101. When the conventional enclosure is switched from the locked state to the unlocked state, the protruding button 301 is first pressed downwardly so that the engaging rod 302 disengages the engaging slot 104, and the upper cover body 2 is then moved so that the engaging rod 302 abuts movably against the inclined guide surface 103 to move into the notch 102.

It is noted that, during operation of the conventional enclosure from the locked state to the unlocked state, friction between the lower housing 1 and the upper cover body 2 increases due to downward pressing of the protruding button 301, thereby hindering movement of the upper cover body 2 relative to the lower housing 1. Furthermore, a displacement direction of the protruding button 301 is perpendicular to that of the upper cover body 2 during operation of the conventional enclosure from the locked state to the unlocked state, thereby resulting in inconvenience during operation. Moreover, permanent deformation of the resilient lock plate 3 may occur as a result of an excessive force acting on the protruding button 301, thereby adversely influencing operation of the locked state.

### SUMMARY OF THE INVENTION

Therefore, the object of the present invention is to provide an enclosure that can be easily operated between a locked state and an unlocked state.

According to the present invention, there is provided an enclosure operable between an unlocked state and a locked state. The enclosure comprises:

a housing having an open top side, two lateral walls opposite to each other in a first direction, and first and second guide rails formed respectively on top ends of the lateral walls, the first guide rail having a notch, a retaining recess disposed adjacent to the notch, and an inclined guide surface portion disposed between the notch and the retaining recess and inclined relative to the lateral walls and the first direction;

a cover body mounted on the housing for covering the open top side of the housing, and movable along the first and second guide rails relative to the housing in a second direction perpendicular to the first direction between an open position, where the cover body partly covers the open top side of the housing, and a closed position, where the cover body fully covers the open top side of the housing, the cover body having a top wall, and first and second flanges extending respectively and downwardly from opposite lateral ends of the top wall and abutting respectively against the first and second guide rails, the top wall having opposite top and bottom surfaces and being formed with two slots disposed adjacent to the first flange, extending in the second direction, and spaced apart from each other in the second direction; and

a switch device mounted on the cover body and including
an operating unit mounted movably on the top wall of the cover body and including
   an operating plate disposed on the top surface of the top wall of the cover body,
   a connecting plate disposed on the bottom surface of the top wall of the cover body, and
   two connecting bolts, each of which extends through the operating plate and a corresponding one of the slots in the top wall of the cover body and is fastened to the connecting plate such that the operating unit is operable so as to move relative to the top wall of the cover body in the second direction between a first limit position and a second limit position, wherein a distance between the first and second limit positions corresponds to a length of each of the slots in the top wall of the cover body,
a lock plate mounted pivotally on the bottom surface of the top wall of the cover body and disposed between the top wall of the cover body and the connecting plate of the operating unit, the lock plate having a pivot end portion connected pivotally to the bottom surface of the top wall of the cover body, and a cam end portion opposite to the pivot end portion direction and formed with an inclined guide slot that corresponds to one of the slots in the top wall of the cover body and that permits extension of a corresponding one of the connecting bolts therethrough, the lock plate being operable so as to rotate relative to the top wall of the cover body between an extending position, where the cam end portion is close to the first flange of the cover body while the operating unit is disposed at the first limit position, and a retracting position, where the cam end portion is distal from the first flange of the cover body while the operating unit is disposed at the second limit position, and
a biasing member mounted between the top wall of the cover body and the lock plate for biasing the lock plate to move toward the extending position.

### BRIEF DESCRIPTION OF THE DRAWINGS

Other features and advantages of the present invention will become apparent in the following detailed description of the preferred embodiment with reference to the accompanying drawings, of which:

FIG. 1 is an exploded perspective view of a conventional enclosure;

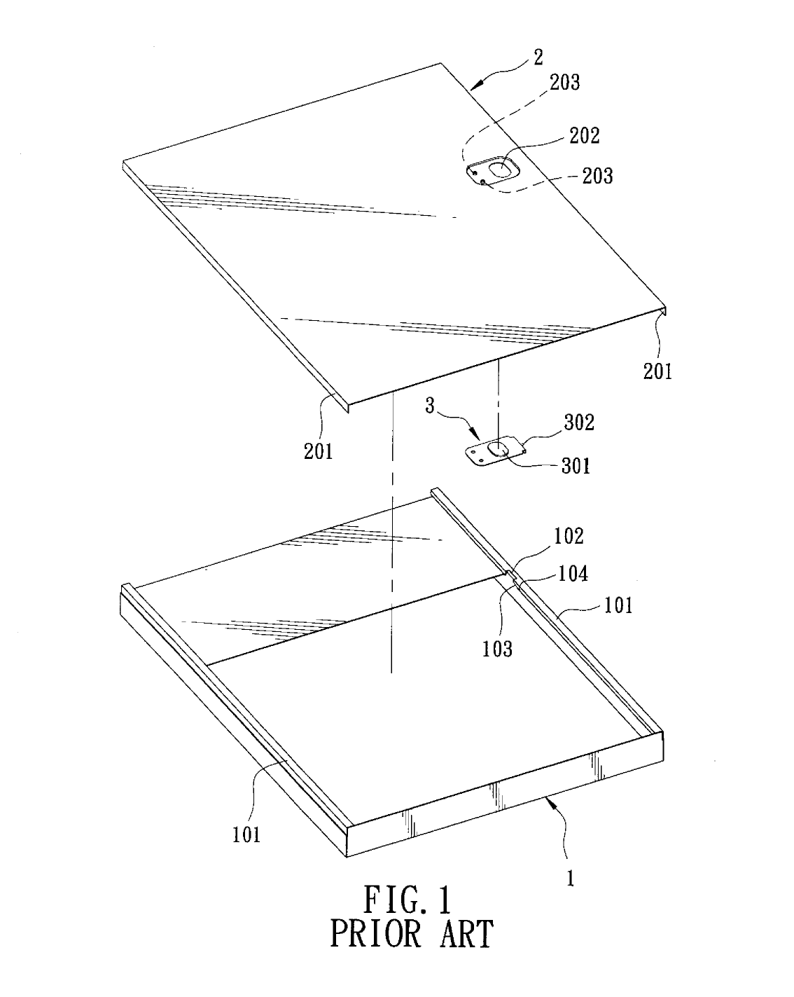

FIG. 2 is a fragmentary assembled schematic view of the conventional enclosure;

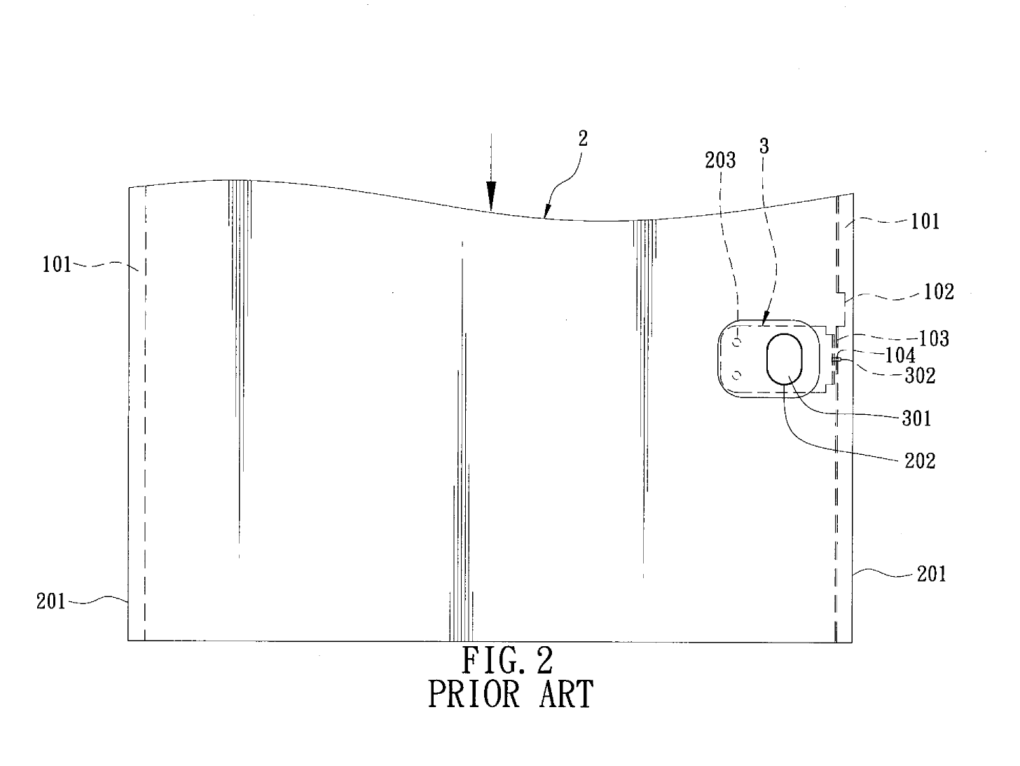

FIG. 3 is an exploded perspective view showing the preferred embodiment of an enclosure according to the present invention;

FIG. 4 is an exploded fragmentary perspective view showing the preferred embodiment;

FIG. 5 is a partly exploded fragmentary perspective view showing the preferred embodiment;

FIG. 6 is a partly cutaway, schematic top view showing the preferred embodiment when operated in an unlocked state;

FIG. 7 is a partly cutaway, schematic top view showing the preferred embodiment when switched from the unlocked state to a locked state;

FIG. 8 is a partly cutaway, schematic top view showing the preferred embodiment when operated in the locked state; and

FIG. 9 is a partly cutaway, schematic top view showing the preferred embodiment when switched from the locked state to the unlocked state.

### DETAILED DESCRIPTION OF THE PREFERRED EMBODIMENT

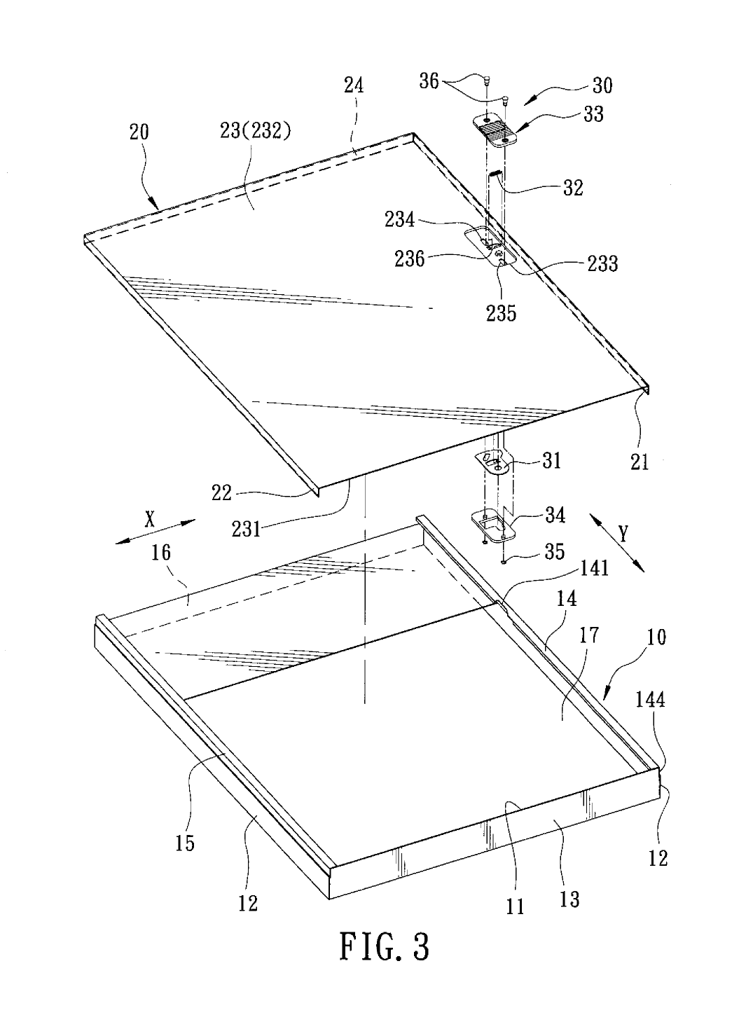

Referring to FIGS. 3 to 5, the preferred embodiment of an enclosure according to the present invention is shown to include a housing 10, a cover body 20, and a switch device 30. The enclosure is operable between an unlocked state and a locked state.

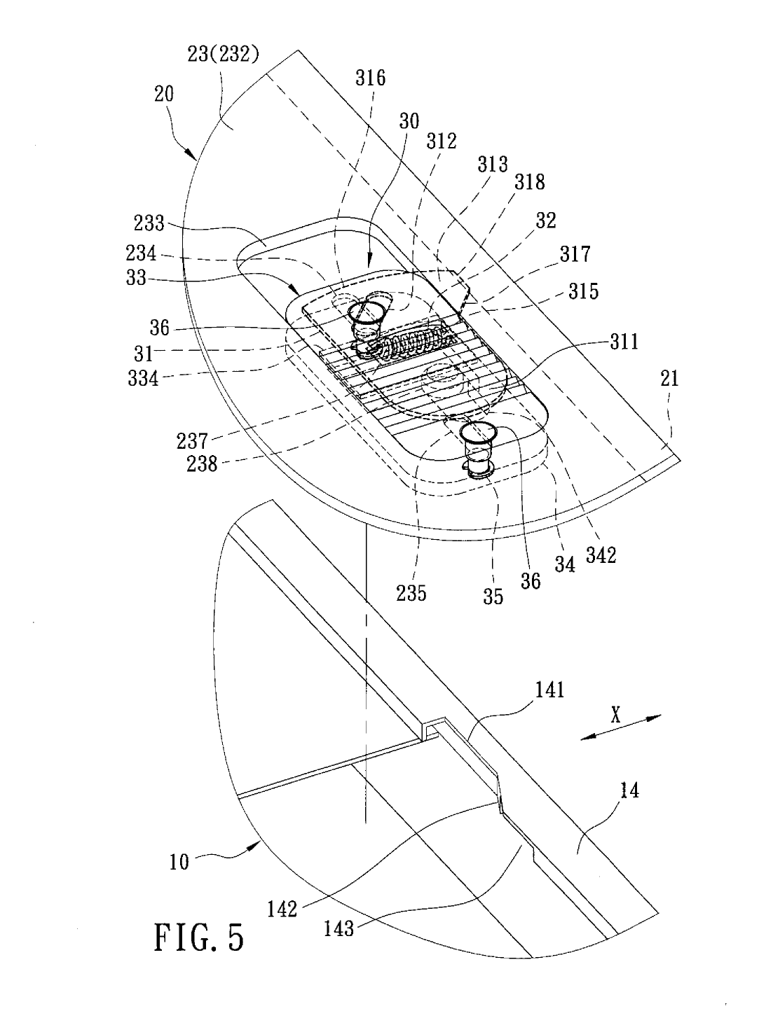

The housing 10 has a bottom wall 17, a front wall 13, a rear wall 16, two lateral walls 12 opposite to each other in a first direction (X), an open top side 11, and first and second elongate guide rails 14, 15 formed respectively on top ends of the lateral walls 12. The first guide rail 14 is formed with a notch 141, and a retaining recess 143 disposed adjacent to the notch 141 and having a closed top end, and has an inclined guide surface portion 142 disposed between the notch 141 and the retaining recess 143 and inclined relative to the first direction (X), as best shown in FIG. 5.

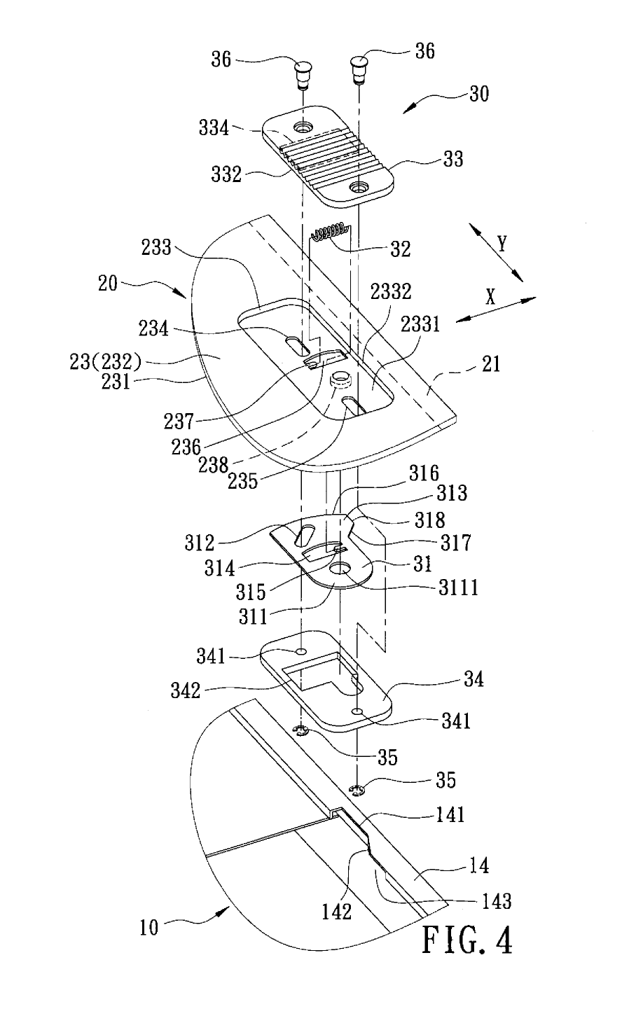

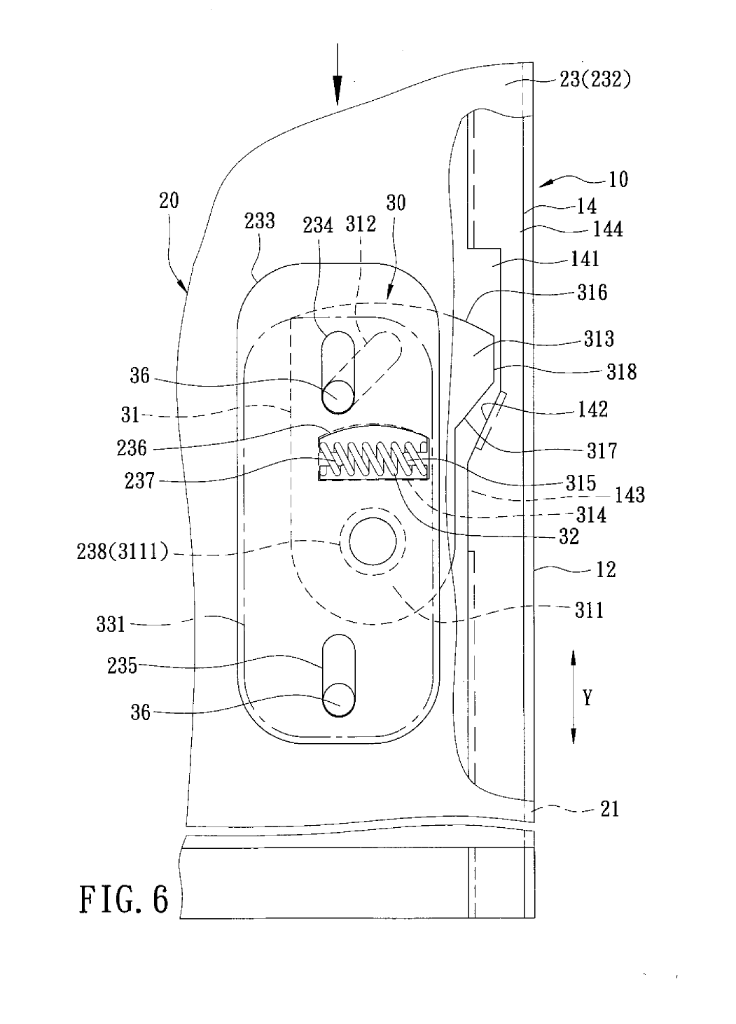

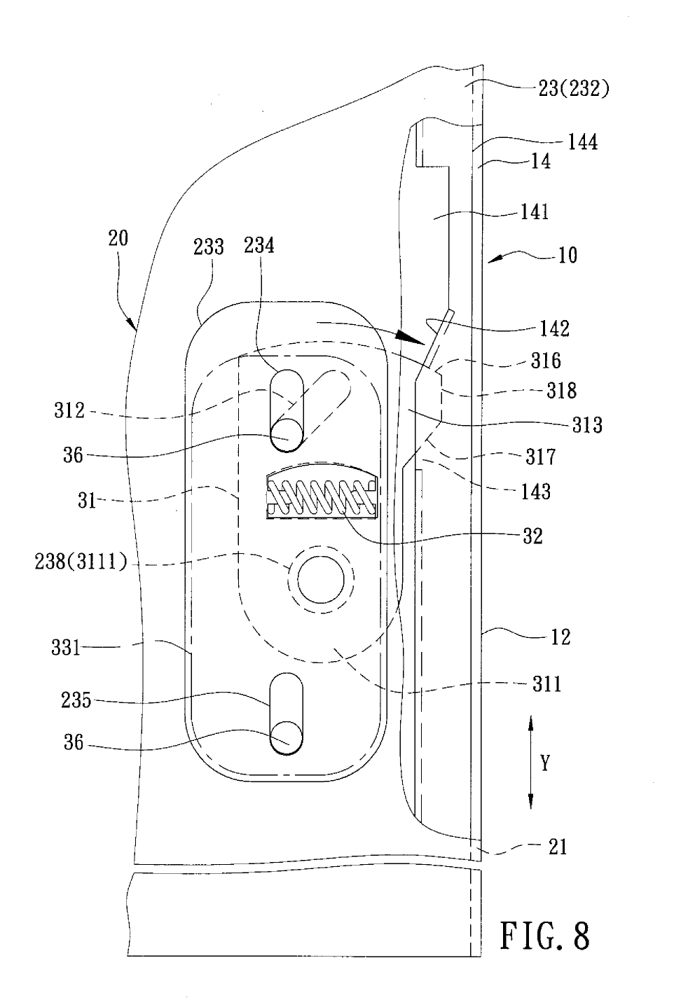

The cover body 20 is mounted on the housing 10 for covering the open top side 11 of the housing 10, and is movable along the first and second guide rails 14, relative to the housing 10 in a second direction (Y) perpendicular to the first direction (X) between an open position, where the cover body 20 partly covers the open top side 11 of the housing 10 (see FIG. 6), and a closed position, where the cover body 20 fully covers the open top side 11 of the housing 10 (see FIG. 8). In this embodiment, the cover body 20 has a top wall 23, first and second flanges 21, 22 extending respectively and downwardly from opposite lateral ends of the top wall 23 and abutting respectively against the first and second guide rails 14, 15, and a third flange 24 extending downwardly from a rear end of the top wall 23. As shown in FIG. 4, the top wall 23 has opposite top and bottom surfaces 232, 231. The top surface 232 of the top wall 23 is formed with a receiving groove 233 that is disposed adjacent to the first flange 21 and that is defined by a groove bottom wall 2331 and a looped surrounding wall 2332. The groove bottom wall 2331 is formed with two slots 234, 235 extending in the second direction (Y) and spaced apart from each other in the second direction (Y), a first mounting hole 236 disposed between the slots 234, 235, extending in the first direction (X), and a first positioning block 237 disposed in the first mounting hole 236. The top wall 23 further has a pivot column 238 extending downwardly from the bottom surface 231 and disposed between the first mounting hole 236 and the slot 235.

The switch device 30 is mounted on the cover body 20, and includes an operating unit, a lock plate 31 and a biasing member 32.

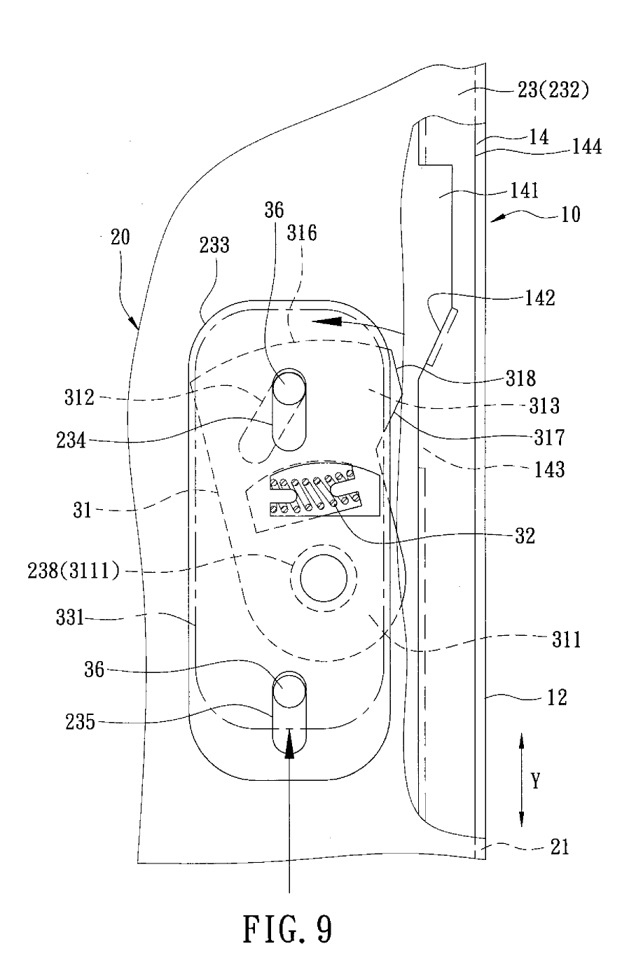

The operating unit is mounted movably on the top wall 23 of the cover body 20, and includes an operating plate 33, a connecting plate 34 and two connecting bolts 36. In this embodiment, the operating plate 33 is received in the receiving groove 233 in the top surface 232 of the top wall 23, and has a bottom surface 332 formed with a receiving recess 334 corresponding to the first mounting hole 236 in the groove bottom wall 2331 of the cover body 20. The connecting plate 34 is disposed on the bottom surface 231 of the top wall 23. In this embodiment, the connecting plate 34 is formed with two through holes 341 spaced apart from each other in the second direction (Y) and corresponding respectively to the slots 234, 235 in the groove bottom wall 2331, and a receiving hole 342 corresponding to the first mounting hole 236 in the groove bottom wall 2331 and permitting extension of the pivot column 238 of the top wall 23 thereinto. The connecting bolts 36 extend through the slots 234, 235 in the groove bottom wall 2331, and the through holes 341 in the connecting plate 34, respectively, and are fastened to the connecting plate 34 by means of two C-shaped retaining rings 35, which are sleeved respectively on ends of the connecting bolts 36, thereby avoiding removal of the connecting bolts 36 from the connecting plate 34. As a result, the operating unit is operable so as to move relative to the top wall 23 of the cover body 20 in the second direction (Y) between a first limit position (see FIG. 6) and a second limit position (see FIG. 9). It is noted that a distance between the first and second limit positions corresponds to a length of each of the slots 234, 235 in the groove bottom wall 2331 of the cover body 20.

The lock plate 31 is mounted pivotally on the bottom surface 231 of the top wall 23 of the cover body 20, and is disposed between the top wall 23 and the connecting plate 34 of the operating unit. The lock plate 31 has a pivot end portion 311 connected pivotally to the bottom surface 231 of the top wall 23, and a cam end portion 313 opposite to the pivot end portion 311 in the second direction (Y) and formed with an inclined guide slot 312 that corresponds to the slot 234 in the cover body 20 and that permits extension of a corresponding one of the connecting bolts 36 therethrough. In this embodiment, the lock plate 31 is formed with a second mounting hole 314 aligned with the first mounting hole 236 in the groove bottom wall 2331, and a second positioning block 315 disposed in the second mounting hole 314 and opposite to the first positioning block 237 in the first direction (X). The pivot end portion 311 is formed with a pivot hole 3111 permitting extension of the pivot column 238 therethrough such that the lock plate 31 is pivotable relative to the top wall 23 of the cover body 20 about the pivot column 238. Furthermore, the cam end portion 313 of the lock plate 31 has a curved edge portion 316, an inclined edge portion 317, and a straight edge portion 318 interconnecting the curved edge portion 316 and the inclined edge portion 317. As a result, the lock plate 31 is operable so as to rotate relative to the top wall 23 between an extending position, as shown in FIG. 6, and a retracting position, as shown in FIG. 9.

The biasing member 32 is mounted between the top wall 23 of the cover body 20 and the lock plate 31 for biasing the lock plate 31 to move toward the extending position. In this embodiment, the biasing member 32 is a coil spring having opposite ends sleeved respectively on the first positioning block 237 of the groove bottom wall 2331 and the second positioning block 315 of the lock plate 31 such that the coil spring is positioned between the first and second mounting blocks 237, 315, and is received in an inner accommodating space defined by the receiving recess 334 in the operating plate 33 of the operating unit, the first mounting hole 236 in the groove bottom wall 2331, the second mounting hole 314 in the lock plate 31 and the receiving hole 342 in the connecting plate 34.

As shown in FIG. 6, when the enclosure is operated in the unlocked state, the cover body 20 is disposed at the open position, the lock plate 31 is disposed at the extending position, and the cam end portion 313 of the lock plate 31 of the switch device 30 extends into the notch 141 in the first guide rail 14 of the housing 10. On the other hand, as shown in FIG. 8, when the enclosure is operated in the locked state, the cover body 20 is disposed at the closed position, the lock plate 31 of the switch device 30 is disposed at the extending position, and the cam end portion 313 of the lock plate 31 of the switch device 30 engages the retaining recess 143 in the first guide rail 14 of the housing 10.

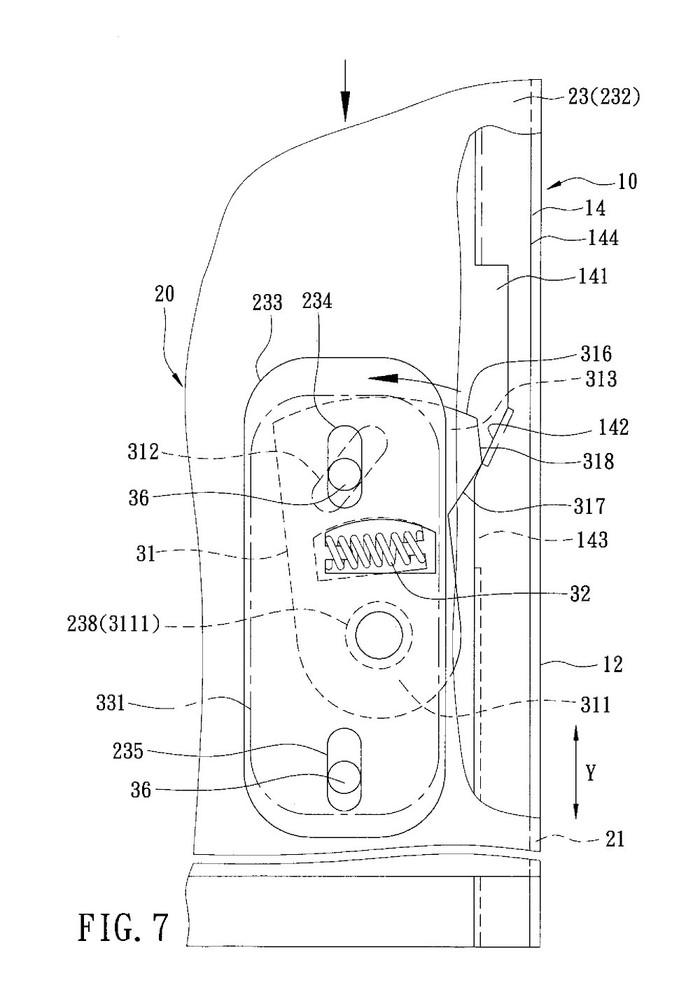

Referring to FIGS. 6 to 8, during operating of the enclosure from the unlocked state to the locked state, the cover body 20 is moved from the open position to the closed position such that the cam end portion 313 is pushed by the inclined guide surface portion 142 to move relative to the top wall 23 of the cover body 26 from the extending position toward the retracting position until the cam end portion 313 does not abut against the inclined guide surface portion 142 of the first guide rail 14, and thus returns to the extending position as a result of a biasing force from the biasing member 32 so as to engage the retaining recess 143 in the first guide rail 14 of the housing 10. It is noted that, when the cover body 20 is moved from the open position to the closed position, the inclined edge portion 317 contacts movably the inclined guide surface portion 142 of the first guide rail 14 of the housing 10 (see FIG. 7) until the cam end portion 313 of the lock plate 31 separates from the notch 141 in the first guide rail 14 of the housing 10, and then the straight edge portion 318 abuts movably against one end of the inclined guide surface portion 142 of the first guide rail 14 of the housing 10 until the cam end portion 313 of the lock plate 31 engages the retaining recess 143 due to the guiding of the curved edge portion 316.

Referring to FIGS. 8, 9 and 6, during operation of the enclosure from the locked state to the unlocked state, the operating unit is moved from the first limiting position to the second limiting position so that the cam end portion 313 of the lock plate 31 is moved from the extending position to the retracting position due to engagement between the inclined guide slot 312 in the lock plate 31 and the corresponding one of the connecting bolts 36, thereby disengaging the retaining recess 143 in the first guide rail 14 of the housing, and the cover body 20 is then moved from the closed position toward the open position while the operating unit is maintained at the second limit position until the cover body 20 reaches the open position.

In such a configuration, the enclosure can be switched from the locked state to the unlocked state using an external force acting on the operating unit to move the operating unit from the first limit position to the second limit position and simultaneously move the cover body 20 from the closed position to the open position. Since a displacement direction of the operating unit is the same as that of the cover body 20 during operation of the enclosure from the locked state to the unlocked state, the enclosure of the present invention can be easily operated as compared to the aforesaid conventional enclosure.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. An enclosure operable between an unlocked state and a locked state, comprising:
a housing having an open top side, two lateral walls opposite to each other in a first direction, and first and second guide rails formed respectively on top ends of said lateral walls, said first guide rail having a notch, a retaining recess disposed adjacent to said notch, and an inclined guide surface portion disposed between said notch and said retaining recess and inclined relative to said lateral walls and the first direction;
a cover body mounted on said housing for covering said open top side of said housing, and movable along said first and second guide rails relative to said housing in a second direction perpendicular to the first direction between an open position, where said cover body partly covers said open top side of said housing, and a closed position, where said cover body fully covers said open top side of said housing, said cover body having a top wall, and first and second flanges extending respectively and downwardly from opposite lateral ends of said top wall and abutting respectively against said first and second guide rails, said top wall having opposite top and bottom surfaces and being formed with two slots disposed adjacent to said first flange, extending in the second direction, and spaced apart from each other in the second direction; and
a switch device mounted on said cover body and including
an operating unit mounted movably on said top wall of said cover body and including
an operating plate disposed on said top surface of said top wall of said cover body,
a connecting plate disposed on said bottom surface of said top wall of said cover body, and
two connecting bolts, each of which extends through said operating plate and a corresponding one of said slots in said top wall of said cover body and is fastened to said connecting plate such that said operating unit is operable so as to move relative to said top wall of said cover body in the second direction between a first limit position and a second limit position, wherein a distance between the first and second limit positions corresponds to a length of each of said slots in said top wall of said cover body,
a lock plate mounted pivotally on said bottom surface of said top wall of said cover body and disposed between said top wall of said cover body and said connecting plate of said operating unit, said lock plate having a pivot end portion connected pivotally to said bottom surface of said top wall of said cover body, and a cam end portion opposite to said pivot end portion and formed with an inclined guide slot that corresponds to one of said slots in said top wall of said cover body and that permits extension of a corresponding one of said connecting bolts therethrough, said lock plate being operable so as to rotate relative to said top wall of said cover body between an extending position, where said cam end portion is close to said first flange of said cover body while said operating unit is disposed at the first limit position, and a retracting position, where said cam end portion is distal from said first flange of said cover body while said operating unit is disposed at the second limit position, and
a biasing member mounted between said top wall of said cover body and said lock plate for biasing said lock plate to move toward the extending position.

2. The enclosure as claimed in claim 1, wherein:
said housing further has a bottom wall having opposite lateral ends from which said lateral walls extend respectively upwardly, a front wall, and a rear wall; and
said cover body further has a third flange extending downwardly from a rear end of said top wall of said cover body.

3. The enclosure as claimed in claim 1, wherein said top surface of said top wall of said cover body is formed with a receiving groove that is disposed adjacent to said first flange for receiving said operating plate of said operating unit of said switch device therein and that is defined by a groove bottom wall and a looped surrounding wall, said groove bottom wall being formed with said slots in said top wall.

4. The enclosure as claimed in claim 3, wherein:
said groove bottom wall of said cover body is further formed with a first mounting hole extending in the first direction, and a first positioning block disposed in said first mounting hole;
said lock plate is formed with a second mounting hole aligned with said first mounting hole, and a second positioning block disposed in said second mounting hole and opposite to said first positioning block in the first direction;
said operating plate of said operating unit has a bottom surface formed with a receiving recess corresponding to said first mounting hole in said groove bottom wall of said cover body;
said connecting plate of said operating unit is formed with a receiving hole corresponding to said second mounting hole in said lock plate; and
said biasing member is a coil spring having opposite ends sleeved respectively on said first positioning block of said groove bottom wall of said cover body and said second positioning block of said lock plate such that said coil spring is positioned between said first and second mounting blocks, and is received in an inner accommodating space defined by said receiving recess in said operating plate of said operating unit, said first mounting hole in said groove bottom wall of said cover body, said second mounting hole in said lock plate and said receiving hole in said connecting plate of said operating unit.

5. The enclosure as claimed in claim 1, wherein:
said connecting plate of said operating unit is formed with two through holes spaced apart from each other and permitting respectively extension of said connecting bolts therethrough; and
said switch device further includes two C-shaped retaining rings sleeved respectively on ends of said connecting bolts, thereby avoiding removal of said connecting bolts from said connecting plate.

6. The enclosure as claimed in claim 1, wherein:
said top wall of said cover body further has a pivot column extending downwardly from said bottom surface of said top wall of said cover body; and
said pivot end portion of said lock plate is formed with a pivot hole permitting extension of said pivot column therethrough such that said lock plate is pivotable relative to said top wall of said cover body about said pivot column.

7. The enclosure as claimed in claim 1, wherein:
said cam end portion of said lock plate has a curved edge portion, an inclined edge portion, and a straight edge portion interconnecting said curved edge portion and said inclined edge portion;
when said cover body is moved from the open position to the closed position, said inclined edge portion contacts movably said inclined guide surface portion of said first guide rail of said housing until said cam end portion of said lock plate separates from said notch in said first guide rail, and then said straight edge portion abuts movably against one end of said inclined guide surface portion of said first guide rail of said housing until said cam end portion of said lock portion engages said retaining recess due to guiding of said curved edge portion.
